(19) United States
(12) Patent Application Publication
(10) Pub. No.: US 2026/0165152 A1
(43) Pub. Date: Jun. 11, 2026

(54) LASER PROCESSING METHOD FOR GLASS SUBSTRATE AND STAGE

(71) Applicant: Absolics Inc., Covington, GA (US)

(72) Inventors: Jong Hyun PARK, Hwaseong-si (KR); Jincheol KIM, Hwaseong-si (KR)

(73) Assignee: Absolics Inc., Covington, GA (US)

(21) Appl. No.: 19/412,739

(22) Filed: Dec. 8, 2025

(30) Foreign Application Priority Data
Dec. 9, 2024 (KR) 10-2024-0181528

(51) Int. Cl. H10W 70/05; B23K 26/53; B23K 26/70; B23K 101/36; B23K 103/00; H10P 72/00; H10P 72/78; H10W 70/63; H10W 70/692

(52) U.S. Cl. CPC H10W 70/095; B23K 26/53; B23K 26/704; H10P 72/0436; H10P 72/78; H10W 70/635; H10W 70/692; B23K 2101/36; B23K 2103/54

(57) ABSTRACT

The embodiments disclose a laser processing method for a glass substrate and a stage. The method comprises: a placement operation of disposing the glass substrate with a space above a stage on which a venting film is disposed; and a processing operation of irradiating a laser onto the glass substrate to form defects, thereby manufacturing the glass substrate in which the defects are formed. The stage, which is applied to laser processing, comprises: a stage main body; a support rim protruding from the stage main body; a stage cavity surrounded by the support rim and open at a top; and a pin permitted to move vertically; wherein the pin is disposed in the stage cavity in a number of one or two or more, and the stage main body has a metal surface.

### CROSS-REFERENCE TO RELATED APPLICATION

This application claims priority of Republic of Korea Patent Application No. 10-2024-0181528, filed on Dec. 9, 2024, the entire disclosure of which is hereby incorporated by reference for all purposes.

### BACKGROUND

### Technical Field

The embodiments relate to a laser processing method for a glass substrate and to a stage that suppresses damage and contamination.

### Description of Related Art

In manufacturing electronic components, implementing circuits on a semiconductor wafer is referred to as a front-end (FE) process, and assembling the wafer into a state usable in actual products is referred to as a back-end (BE) process. The BE processes include a packaging process.

Recently, four core technologies have enabled the rapid advancement of electronic products: semiconductor technology, semiconductor packaging technology, manufacturing process technology, and software technology.

While semiconductor technology has advanced in various aspects—such as linewidths on the order of micrometers or less down to the nanometer scale, cell counts exceeding tens of millions, high-speed operation, and significant heat dissipation—packaging technologies capable of perfectly supporting such advances have relatively not kept pace.

Consequently, the electrical performance of a semiconductor may be determined by the packaging technology and the resulting electrical interconnections rather than by the semiconductor technology itself.

In recent years, glass may be applied as a substrate for high-end packaging. Through-holes are formed in a glass substrate, and a conductive material is applied to the through-holes so that the wiring length between an element and a motherboard is shortened and excellent electrical characteristics may be obtained. Demand has therefore increased for improvements in technologies for processing such glass substrates.

Related art includes U.S. Patent Application Publication No. US 2017/0210114 A1 and Korean Patent No. KR 10-2574243 B.

### SUMMARY

In some embodiments, a stage and a processing method that enable a glass substrate to be processed with excellent yield and precision during laser processing such as forming TGVs (Through-Glass Vias) are provided. Problems such as laser reflection, plume generation, and occurrence of adsorption residues may arise due to contact between the stage or a venting film and the glass substrate. The embodiments provide a laser processing method for a glass substrate and a stage used therefor that solve drawbacks which damage the glass substrate or degrade processing precision.

According to the embodiments, a laser processing method for a glass substrate includes: a placement operation of disposing the glass substrate with a gap above a stage on which a venting film is disposed; and a processing operation of irradiating a laser onto the glass substrate to form defects, thereby manufacturing a glass substrate in which the defects are formed.

The defects, by themselves or through etching, form glass through-vias or glass cavities in the glass substrate.

The stage may include: a stage main body; a support rim protruding from the stage main body; a stage cavity surrounded by the support rim and open at its top; and a pin disposed in the cavity and permitted to move vertically.

A seating pad may be disposed on the support rim.

Vacuum may be applied or released at a location of the seating pad that contacts the glass substrate.

The venting film may be disposed in the stage cavity.

The venting film may suppress reflection of the laser toward the glass-substrate side.

When the laser is irradiated in the processing operation, vacuum may be applied to the seating pad.

When the pin is raised in the processing operation, it may contact the lower surface of the glass substrate.

The glass substrate may be one in which a plurality of individual packaging substrates are arranged with a dummy region therebetween.

When the pin is raised in the processing operation, it may contact a lower surface of the dummy region.

The venting film and the glass substrate may not directly contact each other.

The processing operation may include: a fixing process in which the pin is raised to contact the lower surface of the glass substrate, the position of the glass substrate is fixed, and vacuum is applied to the seating pad to vacuum-chuck the glass substrate; a treating process of irradiating the laser onto the glass substrate; and a releasing process of releasing the vacuum at the seating pad and lowering the pin.

According to the embodiments, another embodiment provides a stage applied to laser processing, the stage including: a stage main body; a support rim protruding from the stage main body; a stage cavity surrounded by the support rim and open at its top; and a pin permitted to move vertically.

The pin may be disposed in the stage cavity in a number of one or two or more.

The stage main body may have a metal surface.

A venting film may be disposed in the stage cavity.

A seating pad may be disposed on the support rim.

A hole or a pattern may be formed in the seating pad, and the hole or pattern may be connected to a vacuum pump.

A glass substrate may be disposed above the stage cavity.

An upper surface of the seating pad may support and positionally fix the glass substrate, and the pin may support a lower surface of the glass substrate.

The venting film may be a porous polymer film.

### BRIEF DESCRIPTION OF THE DRAWINGS

FIG. 1 is a conceptual cross-sectional view illustrating a laser processing operation of a glass substrate according to related art.

FIG. 2 is a schematic cross-sectional view of a stage according to an embodiment.

FIG. 3A is a schematic plan view of the stage according to an embodiment.

FIG. 3B is a schematic plan view illustrating a state in which a glass substrate is disposed on the stage according to an embodiment.

FIGS. 4A to 4D are conceptual cross-sectional views respectively illustrating: placement of the glass substrate on the stage; after a pin is raised, support of the glass substrate and vacuum-chucking fixation of the glass substrate; progress of laser processing; and, upon completion of the laser processing, release of the vacuum fixation of the glass substrate and lowering of the pin.

### DESCRIPTION OF THE EMBODIMENTS

The embodiments will now be described in detail with reference to the accompanying drawings so that those skilled in the art to which the embodiments pertain may readily carry them out. However, the embodiments may be implemented in various different forms and are not limited to the embodiments set forth herein. Throughout the specification, like reference numerals denote like elements.

In this specification, the term “combinations thereof” included in a Markush-type expression means one or more mixtures or combinations selected from the group of components recited in the Markush-type expression, and indicates that one or more selected from the group of the components are comprised.

In this specification, terms such as “first” and “second” or “A” and “B” are used to distinguish between like terms. Unless clearly indicated otherwise by the context, the singular includes the plural.

In this specification, the expression “the ‘˜’ system” may mean that, within a compound, a compound corresponding to “˜” or a derivative of “˜” is included.

In this specification, that B is disposed over A means that B is disposed directly on A or that B is disposed over A with another layer interposed therebetween, and is not to be construed as limited to B being in contact with the surface of A.

In this specification, that B is connected to A means that A and B are directly connected or are connected via another component interposed between A and B, and, unless otherwise stated, is not to be construed as limited to A and B being directly connected.

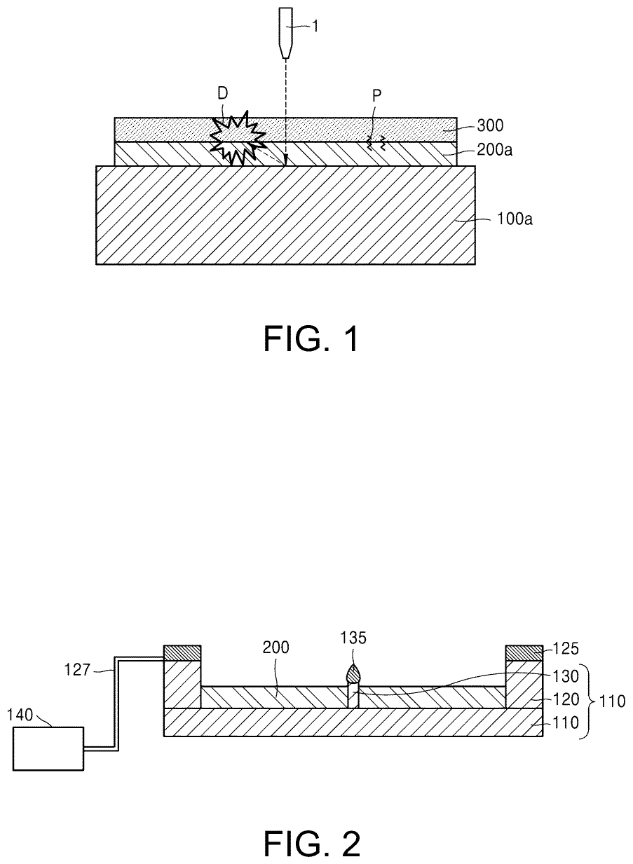

FIG. 1 is a conceptual cross-sectional view illustrating a laser processing operation of a glass substrate according to related art. In laser processing of a glass substrate, a venting film 200a (permeable film) is disposed on a stage 100a, and a glass substrate 300 is disposed thereover. The glass substrate 300 may have warpage; the stage 100a may vacuum-chuck the glass substrate 300 through the venting film 200a to fix its position and alleviate a small degree of warpage. In this state in which the position of the glass substrate 300 is fixed, laser irradiation processing is carried out.

The stage 100a may be made of a metal such as aluminum. Light is likely to be reflected at the surface of such a metal. Since glass is transmissive, a laser 1 irradiated to the glass substrate 300 may pass through the glass substrate 300 and reach the stage 100a, be reflected there, and then be re-incident on the lower surface of the glass substrate 300. This may cause a defect D at an unintended location of the glass substrate 300 and may degrade processing precision. In addition, light of the laser 1 may accelerate aging of the venting film 200a. Direct contact with the venting film 200a may cause contamination or damage to the glass substrate 300, and when aging of the venting film 200a proceeds, contamination may worsen, for example with residue P remaining on the glass substrate 300.

The embodiments propose a method and a stage used therefor that can solve these problems.

### Stage

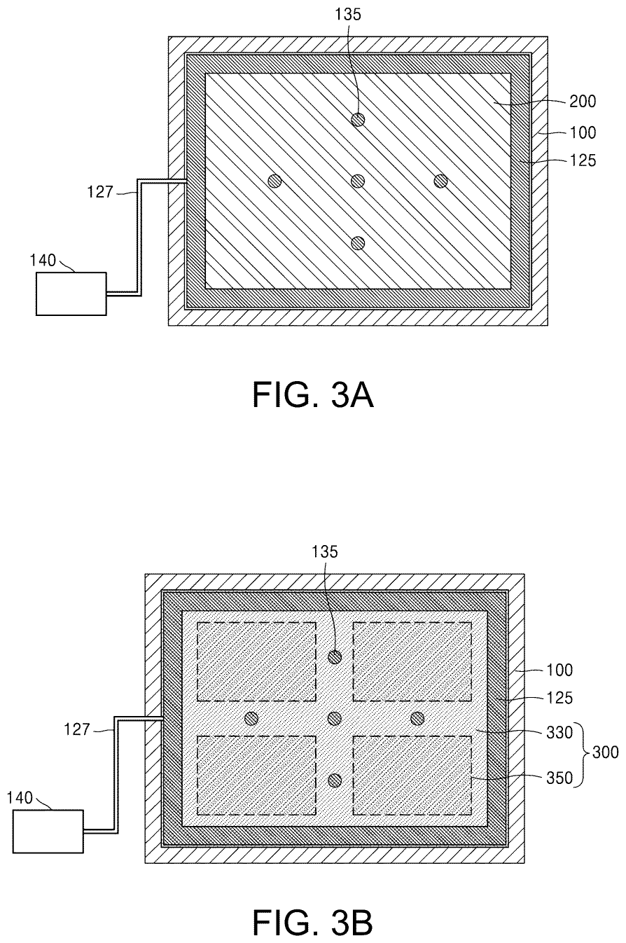

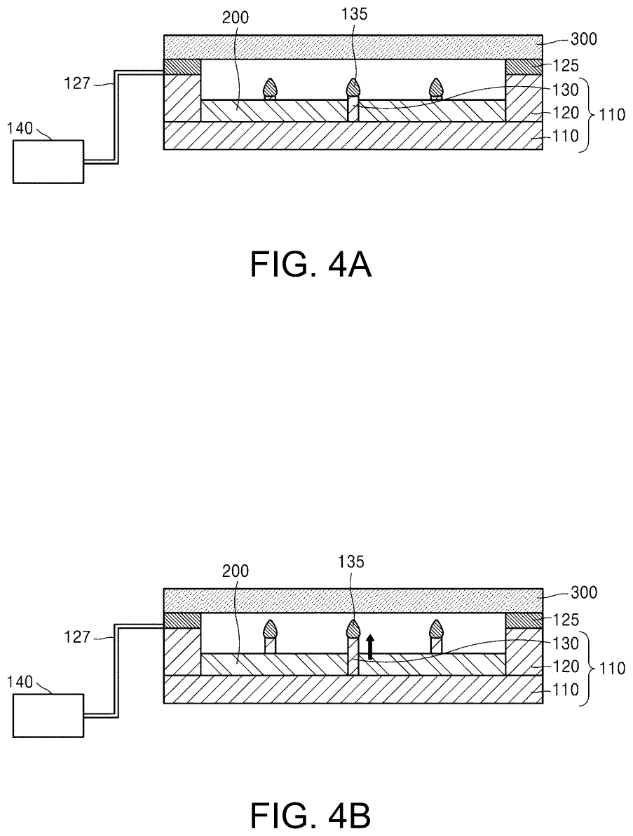

FIG. 2 is a schematic cross-sectional view of a stage according to an embodiment. FIG. 3A is a schematic plan view of the stage according to an embodiment. FIG. 3B is a schematic plan view illustrating a state in which a glass substrate is disposed on the stage according to an embodiment. Referring to FIGS. 2, 3A, and 3B, the embodiment will be described in more detail.

A stage 100 according to an embodiment is applied to laser processing and comprises: a stage main body 110; a support rim 120 protruding from the stage main body 110; a stage cavity surrounded by the support rim 120 and open at its top; and a pin 130 permitted to move vertically.

The stage main body 110 serves to stably support and positionally fix the stage.

Unlike conventional stages, the stage of the embodiment comprises the protruding support rim 120 and the pin 130.

The stage main body 110 is often manufactured from a metal plate such as aluminum.

The stage main body 110 may have a metal surface. By way of example, the stage main body may comprise aluminum or an aluminum alloy.

The support rim 120 is a component protruding from the stage main body 110 to support a glass substrate. In the drawings, the support rim is illustrated as being disposed at an edge of the stage main body 110, but is not limited thereto.

The support rim 120 supports a glass substrate 300 that is disposed on an upper surface of the stage main body 110, and allows a predetermined space (stage cavity) to be present between the upper surface of the stage main body 110 and the glass substrate 300. That is, the support rim 120 supports the glass substrate 300 so that it is in a state of being held above (floating over) the stage main body 110.

The support rim 120 may be formed of the same material as the stage main body.

The support rim 120 may comprise an elastic polymer material.

The support rim 120 may be coated with an elastic polymer material.

A seating pad 125 may further be disposed on the support rim 120.

The seating pad 125 is disposed on the support rim and supports the glass substrate.

The seating pad 125 may, when contacting the glass substrate 300, adsorb and fix the glass substrate while suppressing damage to the glass substrate.

By way of example, the seating pad 125 is provided for adsorption of the glass substrate 300 and may be connected to a vacuum pump 140 via a connection passage 127.

Holes and patterns are formed on a surface and in an interior of the seating pad 125, and the holes and patterns are connected to the connection passage 127 so that vacuum can be applied or released by the vacuum pump 140.

When vacuum is applied to the seating pad 125, the seating pad 125 can vacuum-chuck the glass substrate 300 disposed thereon, thereby fixing the position of the glass substrate 300.

By way of example, the seating pad 125 may be formed of the same material as the support rim 120.

Although the drawings illustrate the connection passage 127 being disposed at a boundary between the seating pad 125 and the support rim 120, the connection passage 127 may extend through the interior of the stage to a lower or side surface of the stage and be connected to the vacuum pump 140.

A space surrounded by the support rim 120 and open at the top is referred to as a stage cavity.

A venting film 200 may be disposed in the stage cavity. Details of the venting film 200 will be described later.

During a laser etching process, a space is maintained between the glass substrate and the stage, and the glass substrate 300 is stably vacuum-chucked and fixed by vacuum applied to the seating pad 125. In addition, it is possible to carry out the etching process while suppressing unnecessary damage to the stage that may be caused by laser light, and while suppressing contamination of the glass substrate that may occur due to direct adhesion between the glass substrate and the upper surface of the stage main body or between the glass substrate and the venting film.

The pin(s) 130 are disposed in the stage cavity and are capable of vertical movement and positional fixing. By way of example, one, two, three, or four or more pins 130 may be disposed in the stage cavity. Further, forty or fewer, thirty-two or fewer, or fifty or fewer pins may be disposed.

The pin 130 serves to support the glass substrate 300. The glass substrate 300 may be of a large area, and sagging may occur at a portion of the glass substrate 300 that is not supported by the support rim 120, which may reduce the accuracy of laser processing. Accordingly, the embodiment applies the pin(s) 130 to support the glass substrate 300 while minimizing a possibility of contamination or damage of the glass substrate 300.

The glass substrate 300 applied in the embodiment may be a glass substrate for semiconductors.

As a semiconductor material, the glass substrate is more difficult to process than a glass substrate for displays. As a semiconductor material, the glass substrate often has fine lines arranged thereon, and therefore more delicate processing is required than for displays. Accordingly, there is a higher risk of defects due to warpage of the glass substrate or relative positional errors.

The pin 130 may be disposed at a position corresponding to a dummy region 330 of the glass substrate 300.

Unlike display materials for which large areas are preferred, a glass substrate for semiconductors used for ultra-small elements or packaging may have a plurality of individual elements arranged on a large-area glass substrate according to a design, which are then separated by dicing or the like.

By way of example, if a portion applied to a substrate for semiconductor packaging is referred to as an individual product region, such individual product regions may be arranged with margins to constitute a product region 350. A plurality of such product regions may be arranged in the glass substrate 300 at mutual intervals. The intervals are referred to as the dummy region(s) 330.

Specifically, the glass substrate 300 may be a strip substrate in which a plurality of individual packaging substrates (individual product regions) are arranged with the dummy region(s) 330 therebetween.

Specifically, the glass substrate 300 may be a quad substrate in which a plurality of strips are arranged with the dummy region(s) 330 therebetween.

Specifically, the glass substrate 300 may be a panel substrate in which a plurality of quads are arranged with the dummy region(s) 330 therebetween.

The glass substrate 300 of the embodiment may be a strip substrate, a quad substrate, or a panel substrate.

The pin 130 may be arranged to correspond to the dummy region(s) 330 of the glass substrate 300. In other words, the pin 130 may be raised to contact the lower surface of the glass substrate 300 to support the glass substrate 300, and in this case, a position at which one end of the pin 130 contacts the lower surface of the glass substrate 300 may be the dummy region 330. In this case, contamination of the product region(s) 350 can be reduced, and the glass substrate can be processed with better yield.

By way of example, FIG. 3B illustrates a state in which a glass substrate 300, on which four product regions 350 are arranged, is disposed on the stage 100 of the embodiment. On the square glass substrate 300, the product regions 350 are arranged with the dummy region(s) 330 therebetween.

A center of gravity of the glass substrate 300 may be located within the dummy region 330. For example, the pin may be disposed at a center of the stage cavity, and the center may be located within the dummy region 330 of the glass substrate.

The pins 130 may be respectively disposed so as to contact a center of the glass substrate 300 and the dummy region(s) 330 between the center and an edge. Although the drawings illustrate an example in which five pins 130 are applied, the number of pins 130 applied is not particularly limited.

By way of example, FIG. 3A illustrates the stage 100 before the glass substrate 300 is placed. Positions of the pins 130 are set to correspond to the dummy region(s) 330 of the glass substrate 300, and the venting film 200 is disposed.

The pin 130 may have a structure (not shown) connected to the stage main body 110 that allows the pin to be inserted or to protrude. The pin 130 is movable vertically so that its height may be adjusted. The pin 130 may also be selectively fixed so as not to descend under a certain pressure while in a protruded state.

A plurality of pins 130 may be arranged on the stage main body 110 at regular intervals in rows and columns. Among the pins 130, those at positions corresponding to the dummy region(s) 330 of the glass substrate 300 to be described later may be selectively moved up and down.

The pin 130 may move vertically in response to pressure. For example, the pin 130 may rise when pressure in the stage cavity decreases, and may be fixed in the raised state. The pin 130 may descend when the pressure in the stage cavity increases, and the lowered state may be maintained.

The pin 130 comprises a pin seating portion 135 disposed at one end.

The pin seating portion 135 is a portion that directly contacts the lower surface of the glass substrate 300 when the pin 130 is raised, and it is preferable that a material having buffering and covering functions be applied.

By way of example, the pin seating portion 135 may comprise a siloxane-based polymer, polyvinyl acetate, polyvinyl acetal, polyvinyl butyral, polyurethane, or polyether block amide.

The pin seating portion 135 may also comprise PTFE (polytetrafluoroethylene), FEP (fluorinated ethylene propylene), PFA (perfluoroalkoxy), or PAEK (polyaryletherketone).

A pin seating portion 135 made of such materials may substantially suppress damage to the glass substrate 300 and help stably fix the position of the glass substrate 300 on the stage 100.

A venting film 200 may be disposed inside the stage cavity.

The venting film 200 may be disposed in the stage cavity so as to be spaced apart from the glass substrate 300.

The venting film 200 may be disposed on an upper surface of the stage cavity.

The venting film 200 may be disposed over an entire bottom surface of the stage cavity except where the pin is disposed.

The venting film 200 may be a porous film applied to processes such as laser processing of semiconductors. By way of example, a Sunmap film (Nitto) may be applied as the venting film 200, but the embodiment is not limited thereto.

The venting film 200 may be, for example, a porous polyethylene film.

The venting film 200 may be, for example, a porous ultra-high-molecular-weight polyethylene film.

The venting film 200 may be, for example, a porous polyethylene film on which an adhesive layer is disposed.

The venting film 200 may be a pad-type film (vacuum pad) that allows air to move through the film while having mechanical strength equal to or greater than a predetermined level.

The venting film 200 may be, for example, a punched film.

The venting film 200 may be, for example, a punched polytetrafluoroethylene film.

The venting film 200 may be a film having low light reflectance. For example, a black Sunmap film may be applied to reduce light reflectivity.

The venting film 200 may have an antistatic function.

A glass substrate 300 may be disposed above the stage cavity, and laser processing may be carried out.

When the glass substrate 300 is disposed over the stage cavity, a space surrounded by the stage cavity and the glass substrate is maintained below the glass substrate 300, and a pin 130 disposed in this space supports a lower surface of the glass substrate 300 to prevent sagging of the glass substrate.

The stage of the embodiment helps more efficient laser processing of the glass substrate by minimizing the possibility of contamination by preventing the glass substrate from coming into direct contact with the venting film, and by reducing damage to the stage itself by disposing the venting film on the bottom of the stage cavity.

### Laser Processing Method for Glass Substrate

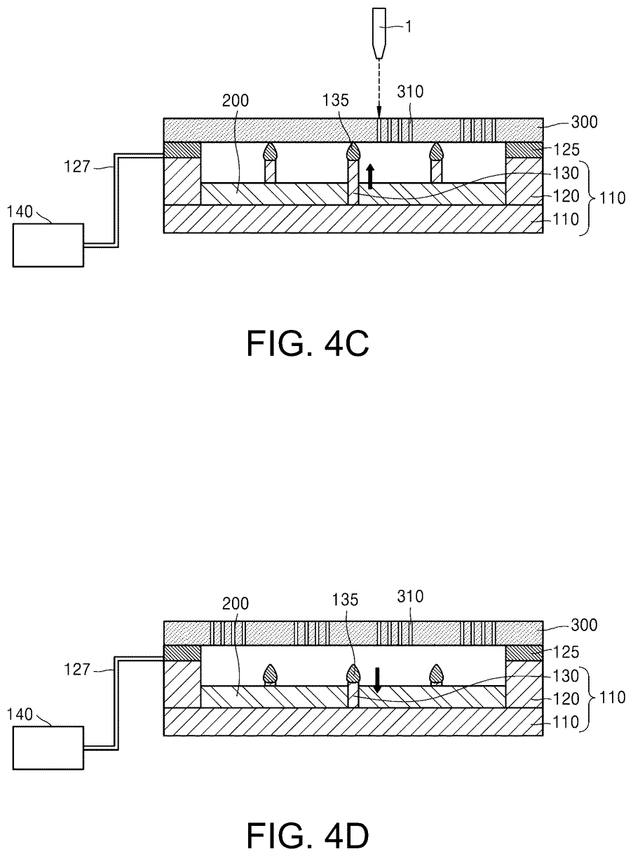

FIGS. 4A to 4D are conceptual cross-sectional views respectively illustrating: placing the glass substrate on the stage; after a pin has risen, supporting the glass substrate and vacuum-chucking fixation of the glass substrate; progress of laser processing; and, after completion of the laser processing, releasing the vacuum fixation of the glass substrate and lowering the pin. The laser processing method for a glass substrate according to the embodiment will be described with reference to FIGS. 4A to 4D.

The laser processing method for a glass substrate according to the embodiment comprises a placement operation and a processing operation, thereby manufacturing a glass substrate 300 in which defects 310 are formed. The defects 310, by themselves or through etching, may form glass through-vias or glass cavities in the glass substrate 300.

The placement operation is an operation of disposing the glass substrate 300 on a stage 100 on which a venting film 200 is disposed (see FIG. 4A). Detailed descriptions of the venting film, the stage, and the glass substrate are omitted here to avoid repetition of the descriptions given above.

The placement may proceed as a process of transferring a glass substrate placed in a cassette to the stage, and, in a cleanroom, the placement may be carried out by a robot arm.

The processing operation is an operation of irradiating a laser 1 onto the glass substrate 300 to form the defects 310.

The processing operation may comprise a fixing process, a treating process, and a releasing process.

The fixing process comprises a process in which the pin(s) 130 rise to contact the lower surface of the glass substrate 300 and support the glass substrate 300. It further comprises a process of vacuum-chucking the glass substrate 300 on a seating pad 120 using a vacuum pump 140 connected to the seating pad 120, thereby fixing the position of the glass substrate 300 (see FIG. 4B).

Specifically, the glass substrate 300 is one in which a plurality of individual packaging substrates are arranged with dummy region(s) 330 therebetween, and, when the pin(s) 130 rise in the processing operation, they may contact a lower surface of the dummy region(s) 330.

The treating process is a process of irradiating the laser 1 onto the glass substrate 300 (see FIG. 4C). The laser irradiation is not limited as long as the laser is applicable to processing of the glass substrate 300. When the laser 1 is irradiated in the processing operation, a state in which the glass substrate 300 is vacuum-chucked using the vacuum pump 140 connected to the seating pad 120 may be maintained.

The releasing process is a process of releasing the vacuum connected to the seating pad 120 and lowering the pin(s) 130 (see FIG. 4D).

Releasing the vacuum connected to the seating pad 120 and lowering the pin(s) may proceed sequentially or may proceed substantially simultaneously.

In this manner, with the glass substrate fixed, a laser beam is irradiated to a predetermined position of the glass substrate to form, in the glass substrate, intended structures such as defects, through-holes, and cavities. If necessary, after the laser irradiation treatment, structures such as through-holes and cavities may be formed in the glass substrate through dry or wet etching.

The processing method of the embodiment applies features such as a stage having a step, a glass-substrate adsorption mechanism, and a pin drive scheme, empties the portion below the laser-processing region as a void, and designs the stage so that the glass substrate is contacted at dummy regions, thereby preventing problems of damage/contamination of the glass substrate due to laser reflection, plume generation, and adhesive (adsorption) residues. In addition, by using the pin(s) and the support rim, planarity of the glass substrate can be kept within a certain level and the precision of laser processing can be improved. Further, the pins are driven selectively so that the pins rise when vacuum connected to the seating pad 120 is applied and descend when the vacuum is released, thereby making attachment and detachment of the glass substrate to and from the stage easier.

The laser processing method for a glass substrate and the stage of the embodiment may solve contamination and damage problems that can occur to the glass substrate during laser processing.

The laser processing method for a glass substrate and the stage of the embodiment may solve problems such as a decrease in processing precision due to laser reflection; plume generation caused by contact between the stage or the venting film and the glass substrate; damage to the venting film due to the laser; and occurrence of adsorption residues on the glass substrate due to such contact.

While preferred embodiments of the present invention have been described above in detail, the scope of the present invention is not limited thereto. Various modifications and improvements made by those skilled in the art using the basic concept of the present invention as defined by the following claims also fall within the scope of the present invention.

What is claimed is:

1. A laser processing method for a glass substrate, comprising:
a placement operation of disposing the glass substrate with a space above a stage on which a venting film is disposed; and
a processing operation of irradiating a laser onto the glass substrate to form defects,
thereby manufacturing the glass substrate in which the defects are formed,
wherein the defects, by themselves or through etching, form glass through-vias or glass cavities in the glass substrate.

2. The method according to claim 1,
wherein the stage comprises:
a stage main body;
a support rim protruding from the stage main body;
a stage cavity surrounded by the support rim and open at a top; and
a pin disposed in the cavity and permitted to move vertically;
wherein a seating pad is disposed on the support rim,
vacuum is applicable or releasable at a location of the seating pad that contacts the glass substrate, and
the venting film is disposed in the stage cavity.

3. The method according to claim 1,
wherein the venting film suppresses reflection of the laser toward a glass-substrate side.

4. The method according to claim 2,
wherein, when the laser is irradiated in the processing operation, the vacuum is applied to the seating pad.

5. The method according to claim 2,
wherein, when the pin rises in the processing operation, the pin contacts a lower surface of the glass substrate.

6. The method according to claim 2,
wherein the glass substrate is one in which a plurality of individual packaging substrates are arranged with a dummy region therebetween, and, when the pin rises in the processing operation, the pin contacts a lower surface of the dummy region.

7. The method according to claim 1,
wherein the venting film and the glass substrate do not directly contact each other.

8. The method according to claim 2,
wherein the processing operation comprises:
a fixing process in which the pin rises to contact a lower surface of the glass substrate, a position of the glass substrate is fixed, and the glass substrate is vacuum-chucked by applying the vacuum to the seating pad;
a treating process of irradiating the laser onto the glass substrate; and
a releasing process of releasing the vacuum at the seating pad and lowering the pin.

9. A stage applied to laser processing, comprising:
a stage main body;
a support rim protruding from the stage main body;
a stage cavity surrounded by the support rim and open at a top; and
a pin permitted to move vertically;
wherein the pin is disposed in the stage cavity in a number of one or two or more,
and the stage main body has a metal surface.

10. The stage according to claim 9,
wherein a venting film is disposed in the stage cavity.

11. The stage according to claim 9,
wherein a seating pad is disposed on the support rim,
holes or a pattern are formed in the seating pad, the holes or the pattern are connected to a vacuum pump,
a glass substrate is disposed above the stage cavity,
an upper surface of the seating pad supports and positionally fixes the glass substrate, and
the pin supports a lower surface of the glass substrate.

12. The stage according to claim 10,
wherein the venting film is a porous polymer film.
